(19) United States
(12) Patent Application Publication
(10) Pub. No.: US 2006/0284231 A1
(43) Pub. Date: Dec. 21, 2006

(54) Dielectric memory and method for manufacturing the same

(76) Inventors: Shinya Natsume, Shiga (JP); Toyoji Ito, Shiga (JP)

Correspondence Address: PANASONIC PATENT CENTER;c/o MCDERMOTT WILL & EMERY LLP, 600 13TH STREET, NW, WASHINGTON, DC, 20005-3096, US

(21) Appl. No.: 11/384,245

(22) Filed: Mar. 21, 2006

(30) Foreign Application Priority Data
Jun. 21, 2005 (JP) 2005-181168

(51) Int. Cl. H01L 27/108; H01L 21/8242

(52) U.S. Cl. 257/306; 438/253; 438/396; 257/532

(57) ABSTRACT

A method for manufacturing a dielectric memory including the steps of: forming a second insulating film which covers wires formed above first contact plugs connected to impurity diffusion layers; forming a third insulating film on the second insulating film; forming a first hydrogen barrier film on the third insulating film; forming capacitors on the first hydrogen barrier film; selectively removing parts of the first hydrogen barrier film located above the first contact plugs; and then heat-treating the capacitors. As the top faces of the first contact plugs are covered with the second and third insulating films during the heat treatment, the first contact plugs are prevented from being oxidized and etched away.

### CROSS-REFERENCE TO RELATED APPLICATION

This non-provisional application claims priority under 35 U.S.C. §119(a) of Japanese Patent Application No. 2005-181168 filed in Japan on Jun. 21, 2005, the entire contents of which are hereby incorporated by reference.

### BACKGROUND OF THE INVENTION

1. Field of the Invention

The present invention relates to a dielectric memory and a method for manufacturing the same. In particular, the present invention relates to a dielectric memory with COB structure and a method for manufacturing the same.

2. Description of Related Art

As to a dielectric memory with so-called COB structure, which is a memory including bit lines below capacitors, deep contact holes are required to form contact plugs for connecting wires above the capacitors and a semiconductor substrate. It is considerably difficult to open the deep contact holes by etching and to fill the deep contact holes with contact plug material. For this reason, stacked contact plugs (hereinafter referred to stack contacts) have been employed in the dielectric memory with the COB structure. This technique allows reduction in aspect ratio of the contact holes for forming the stacked contact plugs. Therefore, the contact holes are easily filled with the contact plug material (for example, see Japanese Unexamined Patent Publication No. H11-251559).

Hereinafter, an explanation of a method for manufacturing a conventional dielectric memory with the COB structure will be provided with reference to FIGS. 12A to 12D and 13A to 13C. FIGS. 12A to 12D and 13A to 13C are sectional views of a major part illustrating the steps of manufacturing the conventional dielectric memory.

First, as shown in FIG. 12A, on parts of a semiconductor substrate 300 which are isolated from each other by an STI region 301, gate electrodes 303 are formed with gate insulating films 302 sandwiched between the gate electrodes 303 and the semiconductor substrate 300 and impurity diffusion layers 304 are formed in the semiconductor substrate 300 to be located on both sides of each of the gate insulating films 302 formed on the semiconductor substrate 300. Thus, transistors each including the gate electrode 303, gate insulating film 302 and impurity diffusion layers 304 are provided on the semiconductor substrate 300.

Next, a first insulating film 305 is formed on the semiconductor substrate 300 to cover the transistors and then flattened by CMP. Then, first contact plugs 306 are formed to penetrate the first insulating film 305 such that each of the first contact plugs 306 is connected to one of the impurity diffusion layers 304 at the bottom thereof.

Subsequently, bit lines 307 are formed on the first insulating film 305 to be electrically connected to the first contact plugs 306. Then, a second insulating film 308 is formed on the first insulating film 305 to cover the bit lines 307 and then flattened by CMP.

Then, as shown in FIG. 12B, a first hydrogen barrier film 309 is formed on the second insulating film 308, and then second contact plugs 310 are formed to penetrate the first insulating film 305, second insulating film 308 and first hydrogen barrier film 309 such that each of the second contact plugs 310 is connected to the other impurity diffusion layer 304 at the bottom thereof.

Then, as shown in FIG. 12B, capacitors 314 each including a bottom electrode 311, a dielectric film 312 and a top electrode 313 are formed on the first hydrogen barrier film 309 such that the capacitors 314 are electrically connected to the second contact plugs 310, respectively. Further, as shown in FIG. 12C, an interlayer insulating film 315 is formed on the first hydrogen barrier film 309 to cover the capacitors 314.

Subsequently, a mask having a desired pattern (not shown) is formed on the interlayer insulating film 315, and then the interlayer insulating film 315 and the first hydrogen barrier film 309 are selectively etched using the mask. Thus, as shown in FIG. 12D, parts of the interlayer insulating film 315 and parts of the first hydrogen barrier film 309 located above the first contact plugs 306 are selectively removed to obtain a memory cell array including a plurality of capacitors 314.

Then, as shown in FIG. 12D, the capacitors 314 are heat-treated in a high temperature oxygen atmosphere to crystallize the dielectric film 312. Then, as shown in FIG. 13A, a second hydrogen barrier film 316 is formed on the second insulating film 308 to cover the interlayer insulating film 315. Thus, the capacitors 314 are enclosed with the first and second hydrogen barrier films 309 and 316.

Then, the second hydrogen barrier film 316 is patterned and a third insulating film 317 is formed over the second insulating film 308 and the second hydrogen barrier film 316. Subsequently, as shown in FIG. 13B, third contact holes 318 are formed to penetrate the second and third insulating films 308 and 317 such that the third contact holes 318 reach the top ends of the first contact plugs 306, respectively.

Then, a conductive film is formed on the third insulating film 317 to fill the third contact holes 318. Then, CMP is performed until the surface of the third insulating film 317 is exposed and part of the conductive film lying out of the third contact holes 318 is removed. Thus, as shown in FIG. 13C, third contact plugs 319 are formed to penetrate the second and third insulating films 308 and 317 such that the third contact plugs 319 are connected to the top ends of the first contact plugs 306, respectively. In this manner, stack contact structure including stacks of the first contact plugs (bottom contact plugs) 306 and the third contact plugs (top contact plugs) 319 is achieved.

### SUMMARY OF THE INVENTION

However, the above-described conventional method for manufacturing the dielectric memory with the COB structure involves the following problems. The problems are detailed with reference to FIGS. 14A to 14C:

According to the conventional method described above, in the step of forming the second insulating film 308 (the step shown in FIG. 12A), gas emission derived from the material for the first contact plugs 306 (e.g., water vapor, hydrogen, fluorine, gaseous hydroxides and other) occurs and holes may be formed in the second insulating film 308 by the emitted gas. Therefore, when CMP is performed on the second insulating film 308 (in the step shown in FIG. 12A), a hole 400a is exposed on the surface of the second insulating film 308 or a scratch 401 may reach a hole 400b as shown in FIG. 14A. Then, when the capacitors 314 are heat-treated (in the step shown in FIG. 12D) as shown in FIG. 14B, oxygen enters the first contact plugs 306 through the hole 400a or the hole 400b to oxidize the first contact plugs 306. As a result, the oxidized first contact plugs 406 increase in contact resistance.

Further, when CMP is performed on the conductive film (in the step shown in FIG. 13C), the oxidized first contact plugs 406 may be etched away by a chemical solution contained in polishing slurry (e.g., hydrogen peroxide water) as shown in FIG. 14C. As a result, cavities are formed to spoil the stack contacts.

In light of the above, an object of the present invention is to prevent oxidation of bottom contact plugs of stack contacts in a dielectric memory with COB structure such that contact resistance at the bottom contact plugs is stabilized and the bottom contact plugs are prevented from being etched away.

In order to achieve the object, a method for manufacturing a dielectric memory according to a first aspect of the present invention includes the steps of: (A) forming a first insulating film on a semiconductor substrate; (B) forming first contact plugs through the first insulating film to reach the semiconductor substrate; (C) forming wires on the first insulating film to be electrically connected to some of the first contact plugs; (D) forming a second insulating film on the first insulating film to cover the wires; (E) forming a third insulating film on the second insulating film; (F) forming a first hydrogen barrier film on the third insulating film; (G) forming second contact plugs through the first insulating film, the second insulating film, the third insulating film and the first hydrogen barrier film to reach the semiconductor substrate; (H) forming capacitors on the first hydrogen barrier film to be electrically connected to the second contact plugs, each of the capacitors including a bottom electrode, a dielectric film and a top electrode; (I) selectively removing parts of the first hydrogen barrier film located above the first contact plugs which are not connected to the wires; and (J) heat-treating the capacitors.

In the method for manufacturing a dielectric memory according to the first aspect of the present invention, the second insulating film is formed and then the third insulating film is formed thereon. The third insulating film blocks or fills holes occurred in the second insulating film during the formation of the second insulating film and exposed on the surface thereof. Further, even if scratches occurred through the polishing of the second insulating film reach the holes in the second insulating film, the third insulating film fills the scratches. Therefore, when the capacitors are heat-treated, the entrance of oxygen into the first contact plugs through the holes or scratches in the second insulating film is prevented, thereby preventing the first contact plugs from oxidation and stabilizing the contact resistance at the first contact plugs. Further, the entrance of oxygen into the wires formed on the first insulating film through the scratches is also prevented, thereby preventing the wires from oxidation.

Further, in the method for manufacturing a dielectric memory according to the first aspect of the present invention, the first hydrogen barrier film is formed over the second insulating film with the third insulating film sandwiched therebetween. As the first hydrogen barrier film is not directly formed on the surface of the second insulating film, stress applied to the second insulating film and the first hydrogen film is alleviated by the third insulating film.

It is preferable that the method for manufacturing a dielectric memory according to the first aspect of the present invention further includes, after the step (J), the steps of: (K) forming a fourth insulating film on the semiconductor substrate to cover the capacitors; and (L) forming third contact plugs through the second insulating film, the third insulating film and the fourth insulating film to reach the first contact plugs, respectively.

As described above, the first contact plugs are not oxidized when the capacitors are heat-treated. Therefore, the third contact plugs reaching the first contact plug are formed through the second, third and fourth insulating films with stable contact resistance. Since the first contact plugs are not oxidized, the first contact plugs are prevented from being etched away by a chemical solution used in the step of forming the third contact plugs (e.g., hydrogen peroxide water). As the first contact plugs are not etched away, the occurrence of cavities that spoil stack contacts including stacks of the first contact plugs and the third contact plugs is prevented.

It is preferable that the method for manufacturing a dielectric memory according to the first aspect of the present invention further includes the step of: (X) forming a second hydrogen barrier film to cover the capacitors and to be joined to the first hydrogen barrier film after the step (J) and before the step (K), wherein in the step (K), the fourth insulating film is formed on the third insulating film to cover the second hydrogen barrier film. As the second hydrogen barrier film is formed after the capacitors are heat-treated, the capacitors are enclosed with the first and second hydrogen barrier films. Therefore, the entrance of hydrogen into the capacitors after the heat treatment of the capacitors is prevented, thereby preventing the deterioration of the characteristic of the capacitors.

It is preferable that the method for manufacturing a dielectric memory according to the first aspect of the present invention further includes the step of: forming an interlayer insulating film on the first hydrogen barrier film to cover the capacitors after the step (H) and before the step (J). By so doing, the interlayer insulating film is formed between the capacitors and the second hydrogen barrier film to cover the capacitors. Therefore, the second hydrogen barrier film improves in coverage.

In the method for manufacturing a dielectric memory according to the first aspect of the present invention, it is preferred that the second insulating film and the third insulating film are made of the same material. By so doing, the second and third insulating films are etched easily without separately adjusting the etching conditions to the second insulating film and the third insulating film. Therefore, the second contact holes for forming the second contact plugs are easily formed through the second and third insulating films by etching. Likewise, the third contact holes for forming the third contact plugs are easily formed through the second and third insulating films by etching.

In order to achieve the above-described object, a method for manufacturing a dielectric memory according to a second aspect of the present invention includes the steps of: (A) forming a first insulating film on a semiconductor substrate; (B) forming first contact plugs through the first insulating film to reach the semiconductor substrate; (C) forming wires on the first insulating film to be are electrically connected to some of the first contact plugs; (D) forming a second insulating film on the first insulating film to cover the wires; (E) forming a first hydrogen barrier film on the second insulating film; (F) forming second contact plugs through the first insulating film, the second insulating film and the first hydrogen barrier film to reach the semiconductor substrate; (G) forming capacitors on the first hydrogen barrier film to be electrically connected to the second contact plugs, each of the capacitors including a bottom electrode, a dielectric film and a top electrode; (H) selectively removing a desired part of the first hydrogen barrier film while at least the capacitors and parts of the first hydrogen barrier film located above the first contact plugs are covered with a mask; and (I) heat-treating the capacitors.

In the method for manufacturing a dielectric memory according to the second aspect of the present invention, the first hydrogen barrier film is removed such that parts of the first hydrogen barrier film located above the first contact plugs are left on the second insulating film and then the capacitors are heat-treated. Therefore, the first hydrogen barrier film blocks or fills holes occurred in the second insulating film during the formation of the second insulating film and exposed on the surface thereof. Further, even if scratches occurred through the polishing of the second insulating film reach the holes in the second insulating film, the first hydrogen barrier film fills the scratches. Therefore, when the capacitors are heat-treated, the entrance of oxygen into the first contact plugs through the holes or scratches in the second insulating film is prevented, thereby preventing the first contact plugs from oxidation and stabilizing the contact resistance at the first contact plugs. Further, the entrance of oxygen into the wires formed on the first insulating film through the scratches is also prevented, the wires are prevented from oxidation.

It is preferable that the method for manufacturing a dielectric memory according to the second aspect of the present invention further includes, after the step (I), the steps of: (J) forming a third insulating film on the semiconductor substrate to cover the capacitors; and (K) forming third contact plugs through the second insulating film, the first hydrogen barrier film and the third insulating film to reach the first contact plugs, respectively.

As described above, the first contact plugs are not oxidized when the capacitors are heat-treated. Therefore, the third contact plugs reaching the first contact plugs are formed through the second insulating film, first hydrogen barrier film and third insulating film with stable contact resistance. Since the first contact plugs are not oxidized, the first contact plugs are prevented from being etched away by a chemical solution used in the step of forming the third contact plugs (e.g., hydrogen peroxide water). As the first contact plugs are not etched away, the occurrence of cavities that spoil stack contacts including stacks of the first contact plugs and the third contact plugs is prevented.

It is preferable that the method for manufacturing a dielectric memory according to the second aspect of the present invention further includes the step of: (X) forming a second hydrogen barrier film to cover the capacitors and to be joined to the first hydrogen barrier film after the step (I) and before the step (J), wherein in the step (J), the third insulating film is formed on the second hydrogen barrier film. As the second hydrogen barrier film is formed after the capacitors are heat-treated, the capacitors are enclosed with the first and second hydrogen barrier films. Therefore, the entrance of hydrogen into the capacitors after the capacitors are heat-treated is prevented, thereby preventing the deterioration of the characteristic of the capacitors.

It is preferable that the method for manufacturing a dielectric memory according to the second aspect of the present invention further includes the step of: forming an interlayer insulating film on the first hydrogen barrier film to cover the capacitors after the step (G) and before the step (I). By so doing, the interlayer insulating film is formed between the capacitors and the second hydrogen barrier film to cover the capacitors. Therefore, the second hydrogen barrier film improves in coverage.

As to the methods for manufacturing a dielectric memory according to the first and second aspects of the present invention, it is preferred that the first hydrogen barrier film is made of silicon nitride. As silicon nitride (SiN) blocks the entrance of hydrogen with high reliability, the first hydrogen barrier film made of SiN is formed thin. Therefore, the first hydrogen barrier film is easily removed in the following step of forming the second contact holes for forming the second contact plugs, thereby making the formation of the second contact plugs easier Moreover, as SiN is one of general semiconductor materials, the first hydrogen barrier film made of SiN is easily worked, and therefore the second contact holes are formed more easily.

In order to achieve the above-described object, a dielectric memory according to an aspect of the present invention includes: a first insulating film which is formed on a semiconductor substrate provided with transistors; first contact plugs which are formed through the first insulating film and connected to ones of diffusion layers in the transistors; wires which are formed on the first insulating film; a second insulating film which is formed on the first insulating film to cover the wires; a first hydrogen barrier film which is formed on the second insulating film; second contact plugs which are formed through the first insulating film, the second insulating film and the first hydrogen barrier film and connected to the other diffusion layers in the transistors; capacitors which are formed on the first hydrogen barrier film and electrically connected to the second contact plugs, each of the capacitors including a bottom electrode, a dielectric film and a top electrode; an interlayer insulating film which is formed on the semiconductor substrate to cover the capacitors; a second hydrogen barrier film which is formed on the interlayer insulating film; a fourth insulating film which is formed on the second hydrogen barrier film to cover the capacitors; and third contact plugs which are formed through the second insulating film and the fourth insulating film to reach the first contact plugs, respectively.

As described above, the first hydrogen barrier film is formed on parts of the second insulating film to be located above the first contact plugs. Therefore, for example, a dielectric memory manufactured by the method according to the second aspect of the present invention is achieved. The first hydrogen barrier film fills holes which are exposed on the surface of the parts of the second insulating film and located above the first contact plugs or blocks the opening of the holes, or fills scratches formed on the surface of the parts of the second insulating film. Therefore, the entrance of oxygen into the first contact plugs through the holes or scratches in the second insulating film is prevented, thereby preventing the first contact plugs from oxidation and stabilizing the contact resistance at the first contact plugs.

In the dielectric memory according to an aspect of the present invention, the first contact plugs are not oxidized. Therefore, the first contact plugs are not etched away by a chemical solution (e.g;, hydrogen peroxide water), thereby preventing the occurrence of cavities that spoil stack contacts including stacks of the first contact plugs and the third contact plugs.

It is preferable that the dielectric memory according to an aspect of the present invention further includes: a third insulating film which is formed between the second insulating film and the first hydrogen barrier film, wherein the second contact plugs are formed through the first insulating film, the second insulating film, the third insulating film and the first hydrogen barrier film and the third contact plugs are formed through the second insulating film, the third insulating film and the fourth insulating film.

As the third insulating film is formed on the second insulating film, the third insulating film fills holes exposed on the surface of the second insulating film or blocks the openings of the holes, or fills scratches formed on the surface of the second insulating film. Therefore, the entrance of oxygen into the first contact plugs through the holes or scratches in the second insulating film is prevented, thereby preventing the first contact plugs from oxidation and stabilizing the contact resistance at the first contact plugs. Further, the entrance of oxygen into the wires formed on the first insulating film through the holes or scratches is prevented, thereby preventing the wires from oxidation.

In the dielectric memory according to an aspect of the present invention, the first hydrogen barrier film is formed over the second insulating film with the third insulating film sandwiched therebetween. As the first hydrogen barrier film is not directly formed on the second insulating film, stress applied to the second insulating film and the first hydrogen barrier film is alleviated by the third insulating film.

In the dielectric memory according to an aspect of the present invention, the first contact plugs are not oxidized. Therefore, the first contact plugs are not etched away by a chemical solution (e.g., hydrogen peroxide water), thereby preventing the occurrence of cavities that spoil stack contacts including stacks of the first contact plugs and the third contact plugs.

Thus, according to the present invention, the top faces of the bottom contact plugs of the stack contacts are covered with the insulating film formed thereon. Therefore, when the capacitors are heat-treated, the contact plugs are prevented from being oxidized and etched away, thereby stabilizing the contact resistance.

### BRIEF DESCRIPTION OF THE DRAWINGS

FIGS. 1A to 1D are sectional views of a major part illustrating the steps of manufacturing a dielectric memory according to Embodiment 1 of the present invention.

FIGS. 2A to 2C are sectional views of a major part illustrating the steps of manufacturing the dielectric memory according to Embodiment 1 of the present invention.

FIGS. 3A to 3C are sectional views of a major part illustrating the steps of manufacturing the dielectric memory according to Embodiment 1 of the present invention.

FIGS. 4A to 4C are sectional views of a major part illustrating the steps of manufacturing the dielectric memory according to Embodiment 1 of the present invention.

FIGS. 5A to 5D are sectional views of a major part illustrating the steps of manufacturing the dielectric memory according to Embodiment 1 of the present invention.

FIGS. 6A and 6B are sectional views of a major part illustrating the steps of manufacturing the dielectric memory according to Embodiment 1 of the present invention.

FIG. 7 is a sectional view illustrating the structure of the dielectric memory according to Embodiment 1 of the present invention.

FIGS. 8A to 8C are sectional views of a major part illustrating the steps of manufacturing a dielectric memory according to Embodiment 2 of the present invention.

FIGS. 9A to 9C are sectional views of a major part illustrating the steps of manufacturing the dielectric memory according to Embodiment 2 of the present invention.

FIGS. 10A to 10D are sectional views of a major part illustrating the steps of manufacturing the dielectric memory according to Embodiment 2 of the present invention.

FIGS. 11A and 11B are sectional views of a major part illustrating the steps of manufacturing the dielectric memory according to Embodiment 2 of the present invention.

FIGS. 12A to 12D are sectional views of a major part illustrating the steps of manufacturing a conventional dielectric memory.

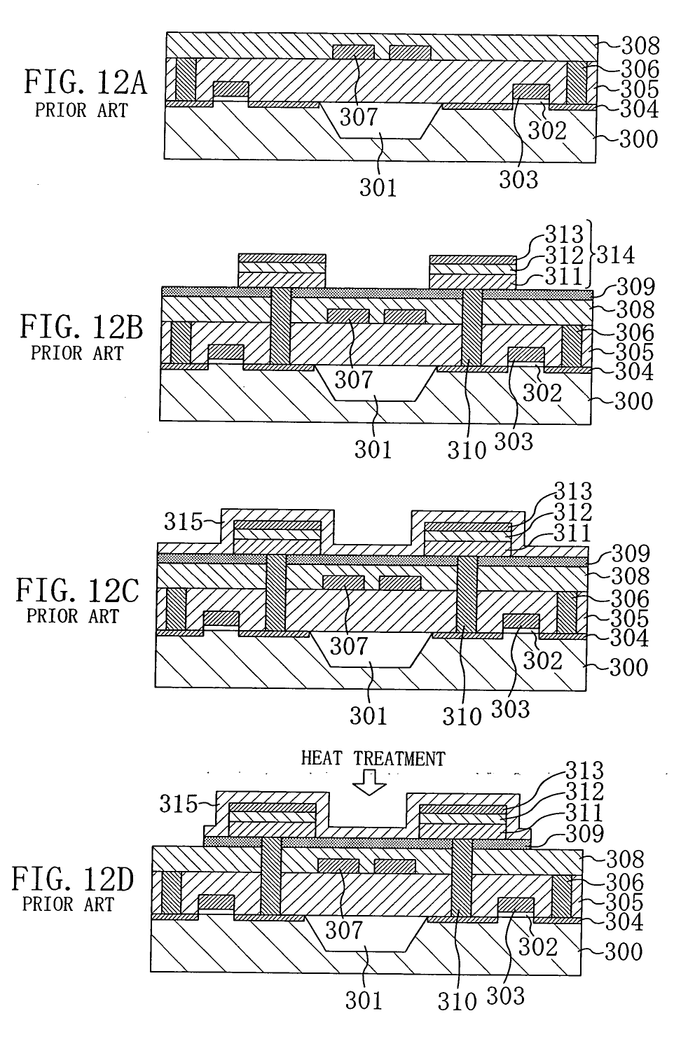

FIGS. 13A to 13C are sectional views of a major part illustrating the steps of manufacturing the conventional dielectric memory.

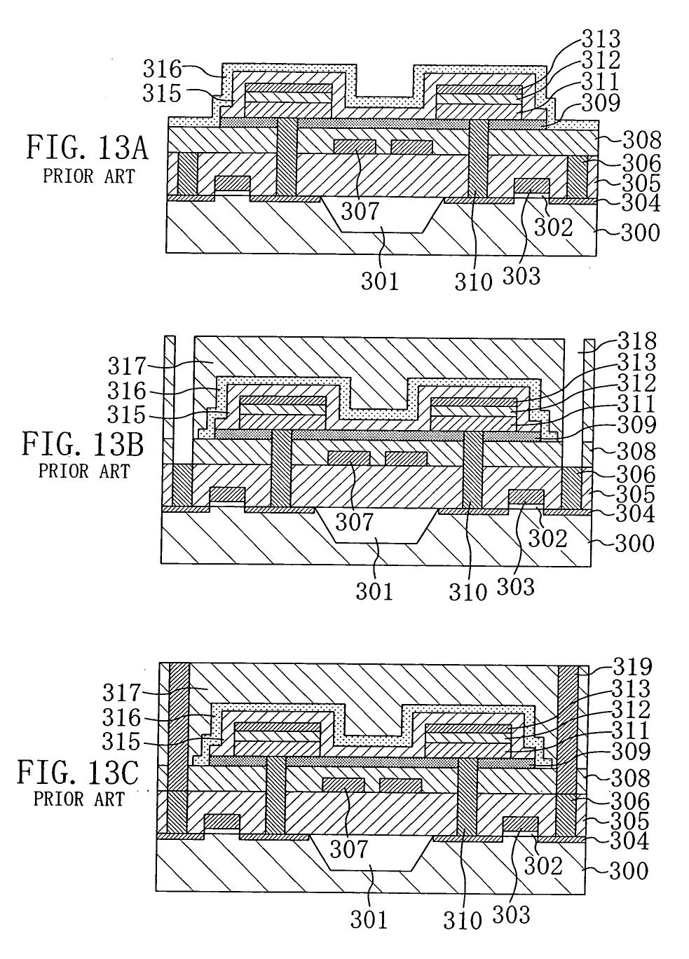

FIGS. 14A to 14C are sectional views of a major part illustrating the steps of manufacturing the conventional dielectric memory.

### DETAILED DESCRIPTION OF THE INVENTION

Hereinafter, an explanation of embodiments of the present invention will be provided with reference to the drawings.

### Embodiment 1

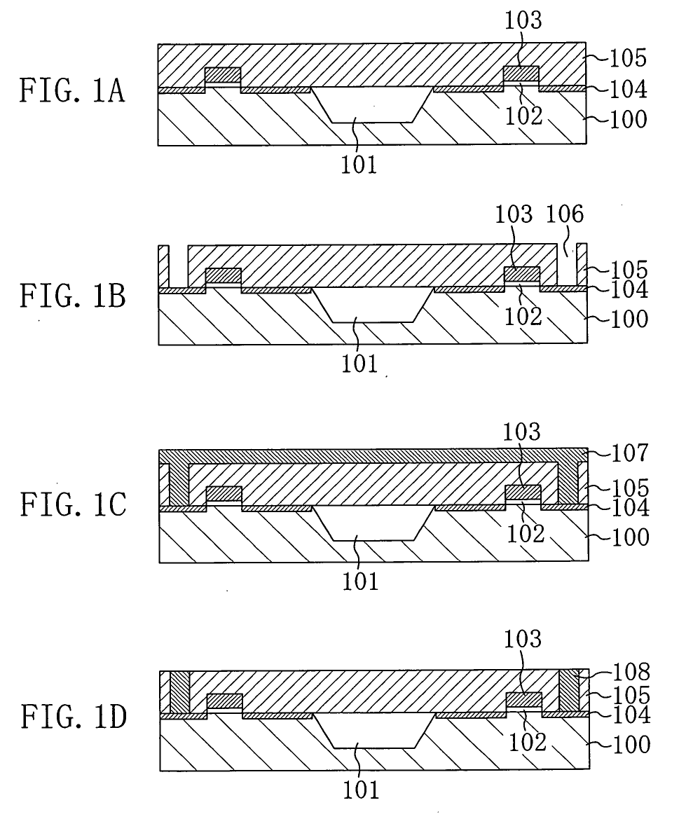

An explanation of a method for manufacturing a dielectric memory of Embodiment 1 of the present invention will be provided with reference to FIGS. 1A to 1D, 2A to 2C, 3A to 3C, 4A to 4C, 5A to 5D and 6A to 6B. FIGS. 1A to 1D, 2A to 2C, 3A to 3C, 4A to 4C, 5A to 5D and 6A to 6B are sectional views of a major part illustrating the steps of manufacturing the dielectric memory according to Embodiment 1 of the present invention. Here, the manufacturing method according to Embodiment 1 of the present invention is applied to a dielectric memory such as a DRAM or a FeRAM.

First, as shown in FIG. 1A, on parts of a semiconductor substrate 100 which are isolated from each other by an STI (Shallow Trench Isolation) region 101, gate electrodes 103 are formed with gate insulating films 102 sandwiched between the gate electrodes 103 and the semiconductor substrate 100 and high concentration impurity diffusion layers 104 are formed in the semiconductor substrate 100 to be located on both sides of each of the gate insulating film 102 formed on the semiconductor substrate 100. Thus, transistors each including the gate electrode 103, gate insulating film 102 and high concentration impurity diffusion layers 104 are provided on the semiconductor substrate 100.

Then, a 0.6 to 1.2 μm thick first insulating film 105 made of BPSG, HDP-NSG or O₃NSG is formed on the semiconductor substrate 100 to cover the transistors by CVD. The first insulating film 105 is then flattened by CMP until the thickness thereof is reduced to 0.4 μm to 0.8 μm.

Next, a resist with a desired pattern (not shown) is formed on the first insulating film 105, and then the first insulating film 105 is etched using the resist as a mask. Thus, as shown in FIG. 1B, first contact holes 106 are formed in the first insulating film 105 such that each of the first contact holes 316 reaches the top face of one of the high concentration impurity diffusion layers 104.

Then, as shown in FIG. 1C, a first conductive film 107 is formed on the first insulating film 105 by sputtering, CVD or plating to fill the first contact holes 106. Examples of material for the first conductive film 107 include metals such as tungsten, molybdenum and titanium, metal nitrides such as titanium nitride and tantalum nitride, metal silicides such as titanium silicide or polysilicon doped with Ti and Ni or Co and Cu.

Then, etch back or CMP is performed until the surface of the first insulating film 105 is exposed and part of the first conductive film 107 lying out of the first contact holes 106 is removed as shown in FIG. 1D. Thus, first contact plugs 108 are formed to penetrate the first insulating film 105 such that each of the first contact plugs 108 is connected to one of the high concentration impurity diffusion layers 104 at the bottom thereof.

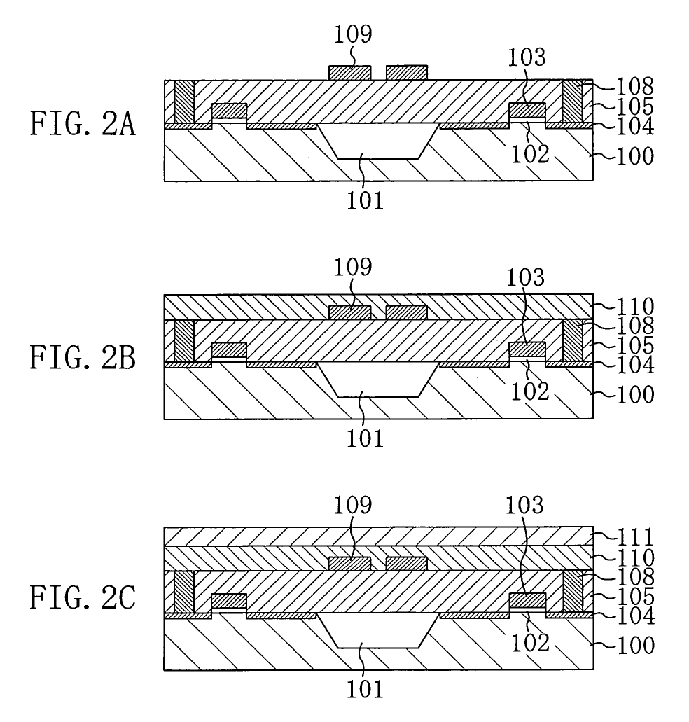

Next, a conductive film made of tungsten (not shown) is formed on the first insulating film 105 and patterned using a mask with a desired pattern (not shown) formed on the conductive film. Thus, as shown in FIG. 2A, bit lines 109 are formed on the first insulating film 105 to be electrically connected to other first contact plugs which are not shown in the figure. The thickness of the bit lines 109 is determined according to wire resistance or a design rule, preferably 20 nm to 150 nm.

Then, as shown in FIG. 2B, a 200 to 800 nm thick second insulating film 110 made of O₃TEOS, BPSG, HDP-NSG or O₃NSG is formed on the first insulating film 105 to cover the bit lines 109, and then flattened by CMP.

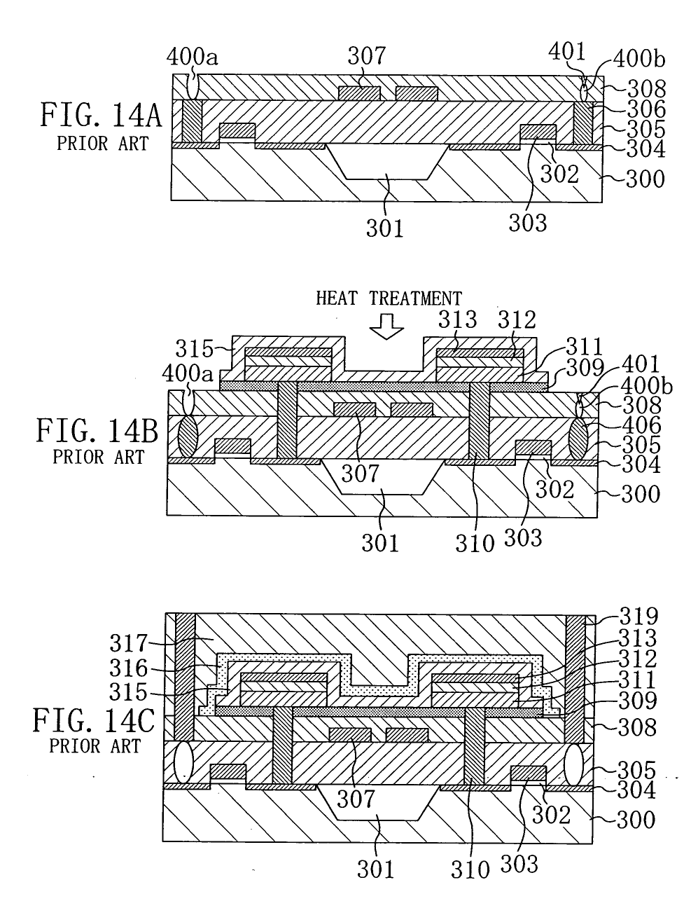

If O₃TEOS is used as the material, the second insulating film 110 is formed at a relatively low temperature. Therefore, in the step of forming the second insulating film 110, gas emission derived from the material for the first contact plugs 108 is prevented from occurring in the second insulating film 110. Therefore, holes by the emitted gas (the holes 400a and 400b shown in FIG. 14A) are prevented from occurring in the second insulating film 110. That is, a film which is less likely to have the holes caused by the emitted gas is a film which is formed at a low temperature. The low temperature mentioned herein is at least 450° C. or lower, more preferably 350° C. or lower.

By the way, a film formed by plasma CVD (plasma CVD film) shows excellent crystallinity. Therefore, if the second insulating film 110 is formed by plasma CVD, scratches (the scratch 401 shown in FIG. 14A) are less likely to occur on the surface of the second insulating film 110 when the second insulating film 110 is subjected to CMP. That is, a film which is less likely to have the scratches on its surface is a film having excellent crystallinity.

Then, as shown in FIG. 2C, a 0.1 to 0.5 μm thick third insulating film 111 made of O₃TEOS, BPSG, HDP-NSG or O₃NSG is formed on the second insulating film 110 by CVD.

According to the method for manufacturing a dielectric memory of the present embodiment, the third insulating film 111 is formed on the second insulating film 110 so as to fill the holes exposed on the surface of the second insulating film 110 (the hole 400a in FIG. 14A) or block the openings of the holes, and fill the scratches formed on the surface of the second insulating film 110 (the scratch 401 in FIG. 14A).

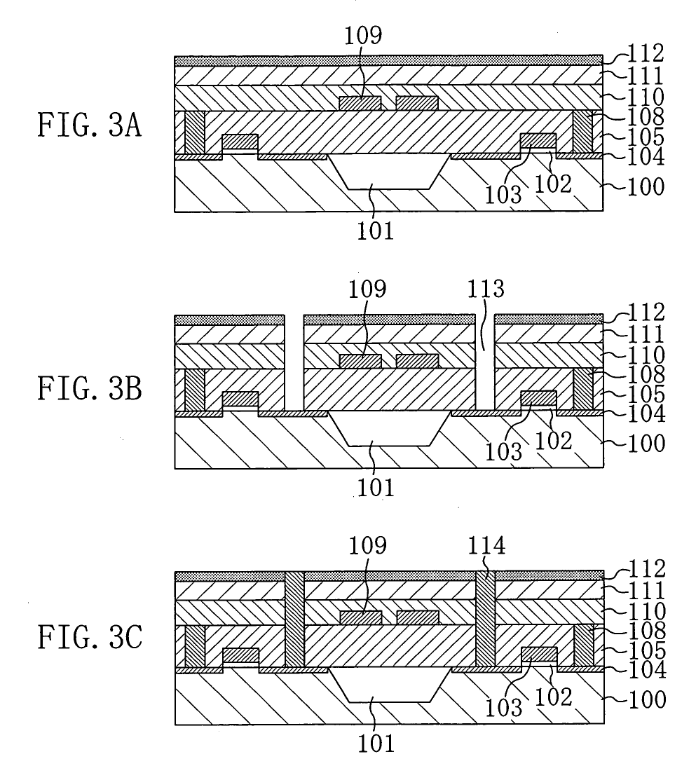

Then, as shown in FIG. 3A, a 10 to 200 nm thick first hydrogen barrier film (a film that blocks the entrance of hydrogen) 112 made of SiN, SiON, TiAlOₓ or TiAlON is formed on the third insulating film 111.

According to the method for manufacturing a dielectric memory of the present embodiment, unlike the conventional technique, the first hydrogen barrier film 112 is not formed directly on the second insulating film 110 but the third insulating film 111 is formed between the first hydrogen barrier film 112 and the second insulating film 110. Since the first hydrogen barrier film 112 is not formed directly on the second insulating film 110, stress applied to the second insulating film 110 and the first hydrogen barrier film 112 is alleviated by the third insulating film 111.

If the first hydrogen barrier film 112 is made of SiN, the first hydrogen barrier film 112 is formed thin because SiN blocks the entrance of hydrogen with high reliability. As the thin first hydrogen barrier film 112 is removed easily, second contact holes 113 are formed easily in the following step (see FIG. 3B). Further, as SiN is one of general semiconductor materials, the first hydrogen barrier film 112 made of SiN is easily worked and the second contact holes 113 are formed more easily.

Then, a resist having a desired pattern (not shown) is formed on the first hydrogen barrier film 112, and then the first hydrogen barrier film 112, third insulating film 111, second insulating film 110 and first insulating film 105 are etched using the resist as a mask. Thus, as shown in FIG. 3B, second contact holes 113 are formed in the first insulating film 105, second insulating film 110, third insulating film 111 and first hydrogen barrier film 112 such that each of the second contact holes 113 reaches the other high concentration impurity diffusion layer 104.

Subsequently, a second conductive film is formed on the first hydrogen barrier film 112 by sputtering, CVD or plating to fill the second contact holes 113. Then, etch back or CMP is performed until the surface of the first hydrogen barrier film 112 is exposed and part of the second conductive film lying out of the second contact holes 113 is removed. Thus, as shown in FIG. 3C, second contact plugs 114 are formed to penetrate the first insulating film 105, second insulating film 110, third insulating film 111 and first hydrogen barrier film 112 such that each of the second contact plugs 114 is connected to the other high concentration impurity diffusion layer 104 at the bottom thereof. Examples of material for the second conductive film include metals such as tungsten, molybdenum and titanium, metal nitrides such as titanium nitride and tantalum nitride, metal silicides such as titanium silicide or polysilicon doped with Ti and Ni or Co and Cu.

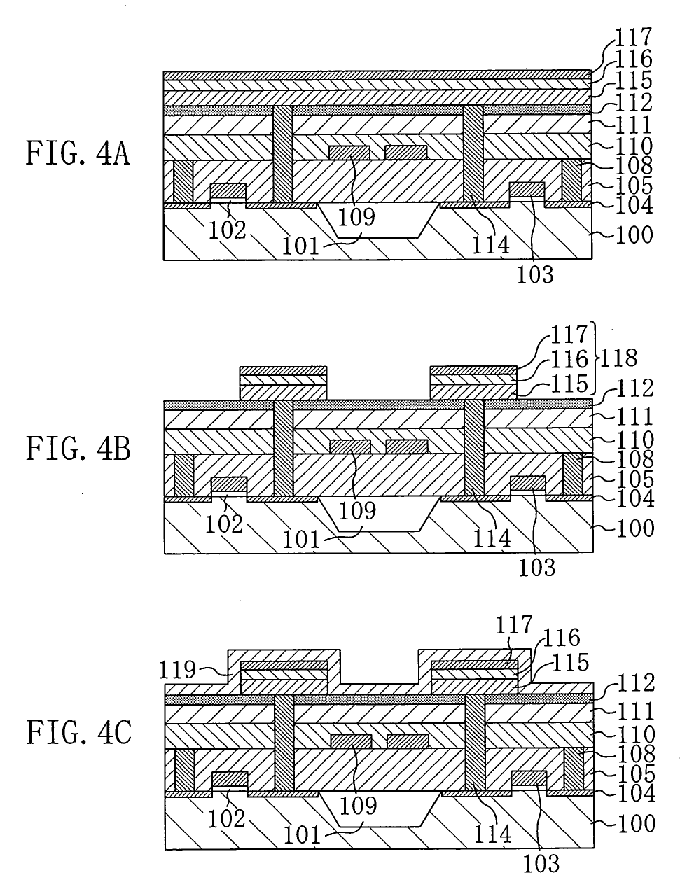

Then, as shown in FIG. 4A, on the first hydrogen barrier film 114, a bottom electrode film 115, a dielectric film 116 and a top electrode film 117 are formed in this order from the bottom. The dielectric film 116 may be made of, for example, BST (BaₓSr₁₋ₓTiO₃)-based dielectric material, Pb-containing perovskite dielectric material such as PZT (Pb(ZrₓTi₁₋ₓ)O₃) or Bi-containing perovskite dielectric material such as SBT (SrBi₂Ta₂O₉).

Then, using a mask with a desired pattern (not shown) formed on the top electrode film 117, the top electrode film 117, dielectric film 116 and bottom electrode film 115 are etched into capacitors 118 each including the bottom electrode film 115, dielectric film 116 and top electrode film 117 on the first hydrogen barrier film 112 as shown in FIG. 4B. In each of the capacitors 118, the bottom surface of the bottom electrode film 115 is connected to the top end of the second contact plug 114.

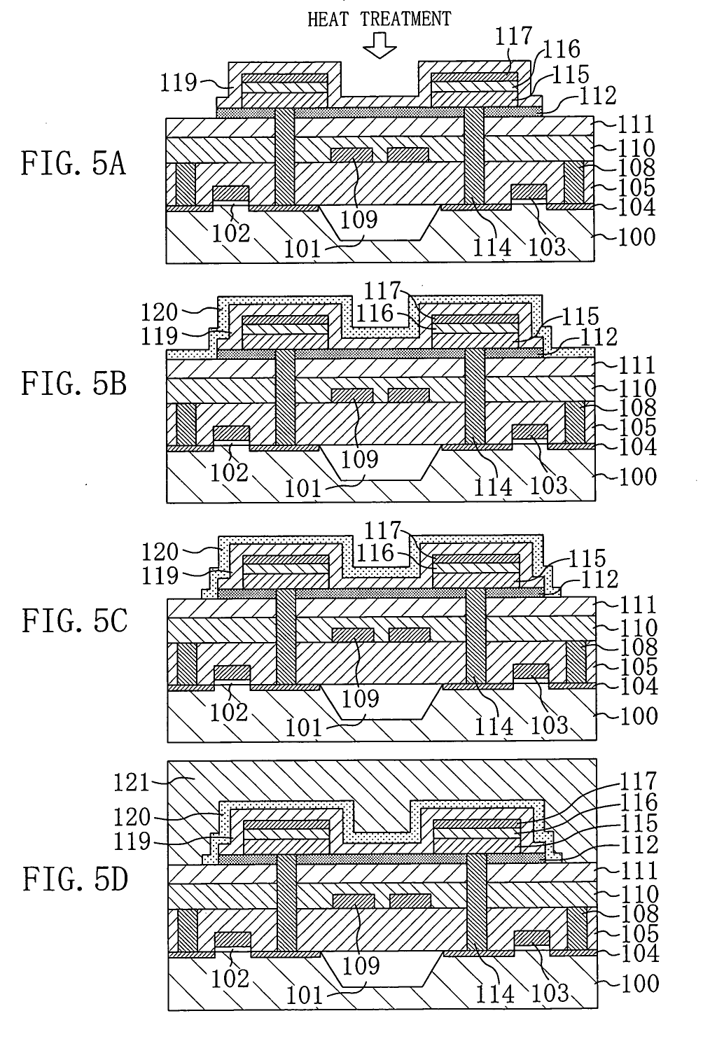

Then, as shown in FIG. 4C, an interlayer insulating film 119 is formed on the first hydrogen barrier film 112 to cover the capacitors 118. The thickness of the interlayer insulating film 119 is 20 to 200 nm, for example. With the presence of the interlayer insulating film 119, a second hydrogen barrier film 120 formed in a later step (see FIG. 5B) improves in coverage.

Then, as shown in FIG. 5A, using a mask with a desired pattern (not shown) formed on the interlayer insulating film 119, the interlayer insulating film 119 and the first hydrogen barrier film 112 are selectively etched. Specifically, parts of the first hydrogen barrier film 112 and parts of the interlayer insulating film 119 located above the first contact plugs 108 are selectively removed. Thus, a memory cell array including a plurality of capacitors 118 is provided on the third insulating film 111.

According to the method for manufacturing a dielectric memory of the present embodiment, as shown in FIG. 5A, the first hydrogen barrier film 112 and the interlayer insulating film 119 are selectively removed without removing the third insulating film 111. Therefore, the holes (the hole 400a shown in FIG. 14A) or the scratches (the scratch 401 shown in FIG. 14A) occurred in the second insulating film 110 are prevented from being exposed outside.

Then, as shown in FIG. 5A, the capacitors 118 are sintered in a high temperature oxygen atmosphere to crystallize the dielectric film 116.

According to the method for manufacturing a dielectric memory of the present embodiment, the capacitors 118 are heat-treated while the third insulating film 111 is formed on the second insulating film 110 and above the first contact plugs 108. Since the holes (the hole 400a shown in FIG. 14A) or the scratches (the scratch 401 shown in FIG. 14A) formed in the second insulating film 110 are not exposed outside during the heat treatment, the entrance of oxygen into the first contact plugs 108 through the holes or scratches is prevented.

Then, as shown in FIG. 5B, a second hydrogen barrier film 120 is formed over the third insulating film 111 and the interlayer insulating film 119 to be joined to the first hydrogen barrier film 112. By so doing, the capacitors 118 are enclosed with the first and second hydrogen barrier films 112 and 120. Therefore, when the capacitors 118 are heat-treated, hydrogen does not enter the capacitors 118, thereby preventing deterioration in characteristic of the capacitors 118.

Then, as shown in FIG. 5C, using a mask with a desired pattern (not shown) formed on the second hydrogen barrier film 120, parts of the second hydrogen barrier film 120 located above the first contact plugs 108 are selectively removed by dry etching.

Then, as shown in FIG. 5D, a 700 to 1500 nm thick fourth insulating film 121 made of BPSG, O₃NSG or HDP-NSG is formed over the third insulating film 111 and the second hydrogen barrier film 120 by CVD and then flattened by CMP.

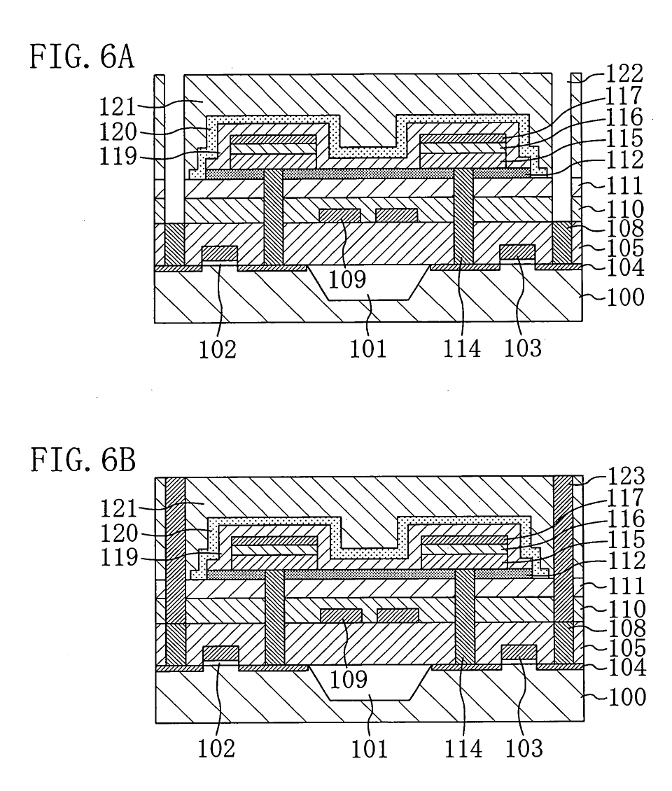

Then, using a mask with a desired pattern (not shown) formed on the fourth insulating film 121, the fourth insulating film 121, third insulating film 111 and second insulating film 110 are etched. Thus, as shown in FIG. 6A, third contact holes 122 are formed in the second insulating film 110, third insulating film 111 and fourth insulating film 121 such that the third contact holes 122 reach the top ends of the first contact plugs 108, respectively.

Then, a third conductive film is formed on the fourth insulating film 121 by sputtering, CVD or plating to fill the third contact holes 122. Then, CMP is performed until the surface of the fourth insulating film 121 is exposed and part of the third conductive film lying out of the third contact holes 122 is removed. Thus, as shown in FIG. 6B, third contact plugs 123 are formed to penetrate the second insulating film 110, third insulating film 111 and fourth insulating film 121 such that the third contact plugs 123 are connected to the top ends of the first contact plugs 108 at the bottom thereof, respectively. Examples of material for the third conductive film include metals such as tungsten, molybdenum and titanium, metal nitrides such as titanium nitride and tantalum nitride, metal silicides such as titanium silicide, or polysilicon doped with Ti and Ni or Co and Cu.

In the above-described manner, a dielectric memory with COB structure including stack contacts formed by stacks of the first contact plugs (bottom contact plugs) 108 and the third contact plugs (top contact plugs) 123 is obtained.

According to the method for manufacturing a dielectric memory of the present embodiment, the second insulating film 110 is formed (FIG. 2B) and then the third insulating film 111 is formed on the second insulating film 110 (FIG. 2C). Therefore, even if the holes occurred in the second insulating film 110 during the formation thereof (the hole 400a shown in FIG. 14A) are exposed on the surface of the second insulating film 110 after polishing, the third insulating film 111 formed thereon fills the holes or blocks the openings of the holes.

Further, even if the scratches occurred on the surface of the second insulating film 110 through the polishing of the second insulating film 110 (the scratch 401 shown in FIG. 14A) reach the holes in the second insulating film 110 (the hole 400b shown in FIG. 14A), the third insulating film 111 fills the scratches formed on the surface of the second insulating film 110.

Therefore, when the capacitors 118 are heat-treated (see FIG. 5A), the third insulating film 111 prevents the entrance of oxygen into the first contact plugs 108 through the holes exposed on the surface of the second insulating film 110 or the scratches reaching from the surface to the holes inside the second insulating film 110. As a result, the first contact plugs 108 are prevented from oxidation, thereby stabilizing the contact resistance at the first contact plugs 108.

Further, since the third insulating film 111 fills the scratches formed on the surface of the second insulating film 110 (the scratch 401 shown in FIG. 14A), the entrance of oxygen into the bit lines 109 formed on the first insulating film 105 through the scratches is prevented. Therefore, the bit lines 109 are prevented from oxidation.

According to the method for manufacturing a dielectric memory of the present embodiment, the first contact plugs 108 are not oxidized when the capacitors 118 are heat-treated (see FIG. SA). Therefore, as shown in FIG. 6B, the third contact plugs 123 which penetrate the second insulating film 110, third insulating film 111 and fourth insulating film 121 to reach the first contact plugs 108 are provided with stable contact resistance.

As the first contact plugs 108 are not oxidized, the first contact plugs 108 are not etched away by a chemical solution contained in polishing slurry (e.g., hydrogen peroxide water) used to polish the third conductive film by CMP in the step of forming the third contact plugs 123 (see FIG. 6B). Therefore, the first contact plugs 108 are prevented from being removed away, thereby preventing the occurrence of cavities that spoil the stack contacts including stacks of the first and third contact plugs 108 and 123.

According to the method for manufacturing a dielectric memory of the present embodiment, the second and third insulating film 110 and 111 may be made of O₃TEOS, BPSG, HDP-NSG or O₃NSG.

It is preferable that the second and third insulating films 110 and 111 are made of the same material. By so doing, the second and third insulating films 110 and 111 are easily etched without separately adjusting the etching conditions to the second insulating film 110 and the third insulating film 111. Therefore, the second and third contact holes 113 and 122 are easily formed.

According to the method for manufacturing a dielectric memory of the present embodiment, the bit lines 109 made of W (tungsten) are formed directly on the first insulating film 105 as shown in FIG. 2A. However, the present invention is not limited thereto. For example, the bit lines made of W may be formed on an adhesion layer which is made of TiN/Ti and formed on the first insulating film 105.

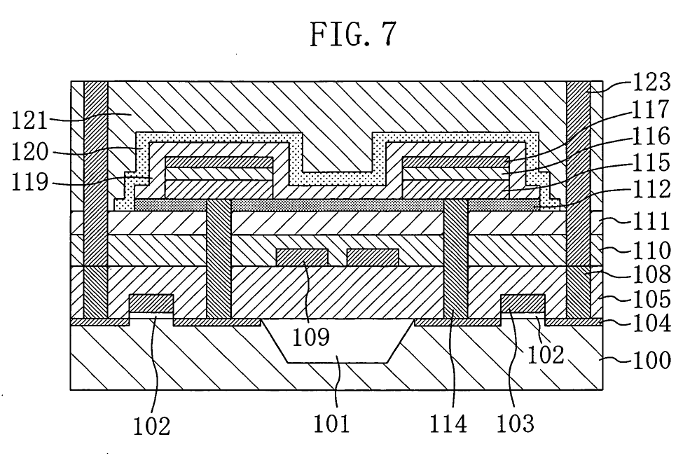

Now, an explanation of a dielectric memory according to Embodiment 1 of the present invention will be provided with reference to FIG. 7. FIG. 7 is a sectional view illustrating the structure of the dielectric memory according to Embodiment 1 of the present invention.

In the dielectric memory according to the present embodiment, the third insulating film 111 is formed on the second insulating film 110 as shown in FIG. 7. Therefore, the third insulating film 111 fills the holes exposed on the surface of the second insulating film 110 (the hole 400a shown in FIG. 14A) or blocks the openings of the holes, or fills the scratches formed on the surface of the second insulating film 110 (the scratch 401 shown in FIG. 14A).

As the third insulating film 111 formed on the second insulating film 110 prevents the entrance of oxygen into the first contact plug 108 through the holes exposed on the surface of the second insulating film 110 or the scratches reaching from the surface to the holes inside the second insulating film 110, the first contact plugs 108 are prevented from oxidation. As a result, the contact resistance at the first contact plugs 108 is stabilized.

### Embodiment 2

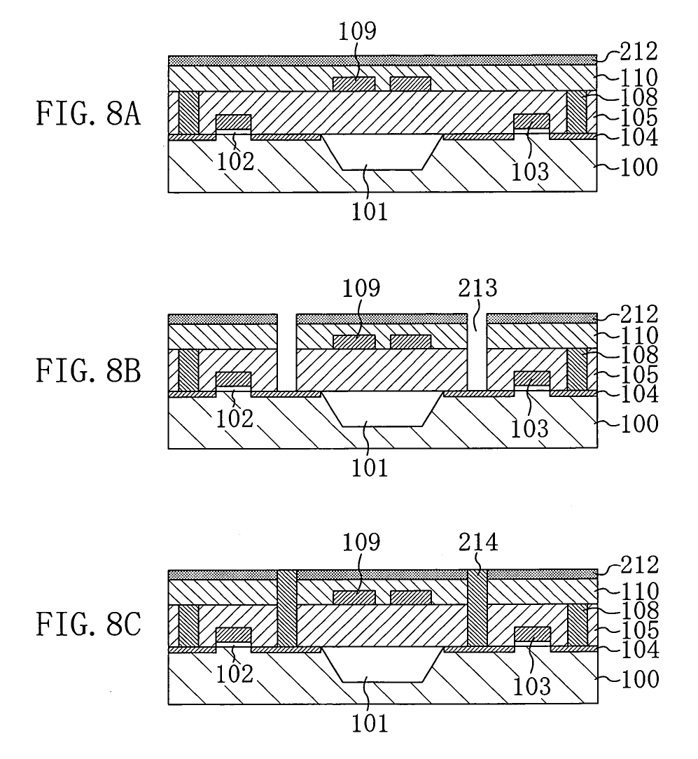

Hereinafter, an explanation of a method for manufacturing a dielectric memory of Embodiment 2 of the present invention will be provided with reference to FIGS. 8A to 8C, 9A to 9C, 10A to 10D and 11A to 11B. FIGS. 8A to 8C, 9A to 9C, 10A to 10D and 11A to 11B are sectional views of a major part illustrating the steps of manufacturing the dielectric memory according to Embodiment 2 of the present invention. In the above-listed figures, the same components as those of the dielectric memory according to Embodiment 1 are indicated by the same reference numerals. Therefore, in the present embodiment, the same manufacturing steps as those of the method of Embodiment 1 are not explained in detail.

First, after the steps illustrated in o FIGS. 1A to 1D and 2A and 2B, a 10 to 200 nm thick first hydrogen barrier film 212 made of SiN, SiON, TiAlOₓ or TiAlON is formed on the second insulating film 110 as shown in FIG. 8A. If the first hydrogen barrier film 212 is made of SiN, the first hydrogen barrier film 212 is formed thin because SiN blocks the entrance of hydrogen with high reliability. As the thin first hydrogen barrier film 212 is removed easily, second contact holes 213 are formed easily in the following step (see FIG. 8B). Further, as SiN is one of general semiconductor materials, the first hydrogen barrier film 212 made of SiN is easily worked and the second contact holes 213 are formed more easily.

Then, a resist having a desired pattern (not shown) is formed on the first hydrogen barrier film 212, and then the first hydrogen barrier film 212, second insulating film 110 and first insulating film 105 are etched using the resist as a mask. Thus, as shown in FIG. 8B, second contact holes 213 are formed in the first insulating film 105, second insulating film 110 and first hydrogen barrier film 212 such that each of the second contact holes 213 reaches the high concentration impurity diffusion layer 104.

Subsequently, a second conductive film is formed on the first hydrogen barrier film 212 by sputtering, CVD or plating to fill the second contact holes 213. Then, etch back or CMP is performed until the surface of the first hydrogen barrier film 212 is exposed and part of the second conductive film lying out of the second contact holes 213 is removed. Thus, as shown in FIG. 8C, second contact plugs 214 are formed to penetrate the first insulating film 105, second insulating film 110 and first hydrogen barrier film 212 such that each of the second contact plugs 214 is connected to the high concentration impurity diffusion layer 104 at the bottom thereof. Examples of material for the second conductive film include metals such as tungsten, molybdenum and titanium, metal nitrides such as titanium nitride and tantalum nitride, metal silicides such as titanium silicide or polysilicon doped with Ti and Ni or Co and Cu.

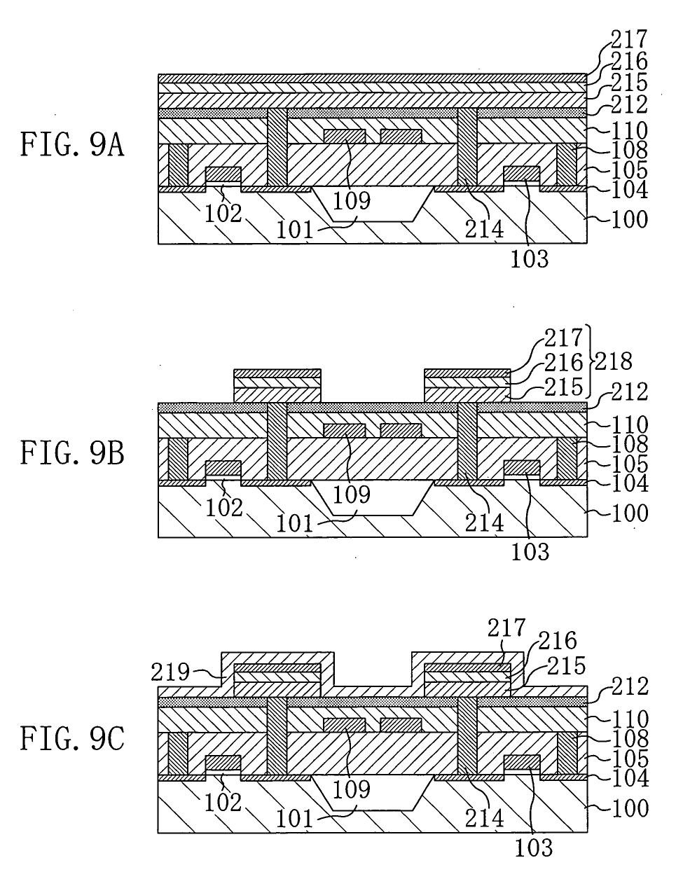

Then, as shown in FIG. 9A, on the first hydrogen barrier film 212, a bottom electrode film 215, a dielectric film 216 and a top electrode film 217 are formed in this order from the bottom. The dielectric film 216 may be made of, for example, BST (BaₓSr₁₋ₓTiO₃)-based dielectric material, Pb-containing perovskite dielectric material such as PZT (Pb(ZrₓTi₁₋ₓ)O₃) or Bi-containing perovskite dielectric material such as SBT (SrBi₂Ta₂O₉).

Then, using a mask with a desired pattern (not shown) formed on the top electrode film 217, the top electrode film 217, dielectric film 216 and bottom electrode film 215 are etched into capacitors 218 each including the bottom electrode film 215, dielectric film 216 and top electrode film 217 on the first hydrogen barrier film 212 as shown in FIG. 9B. In each of the capacitors 218, the bottom surface of the bottom electrode film 215 is connected to the top end of the second contact plug 214.

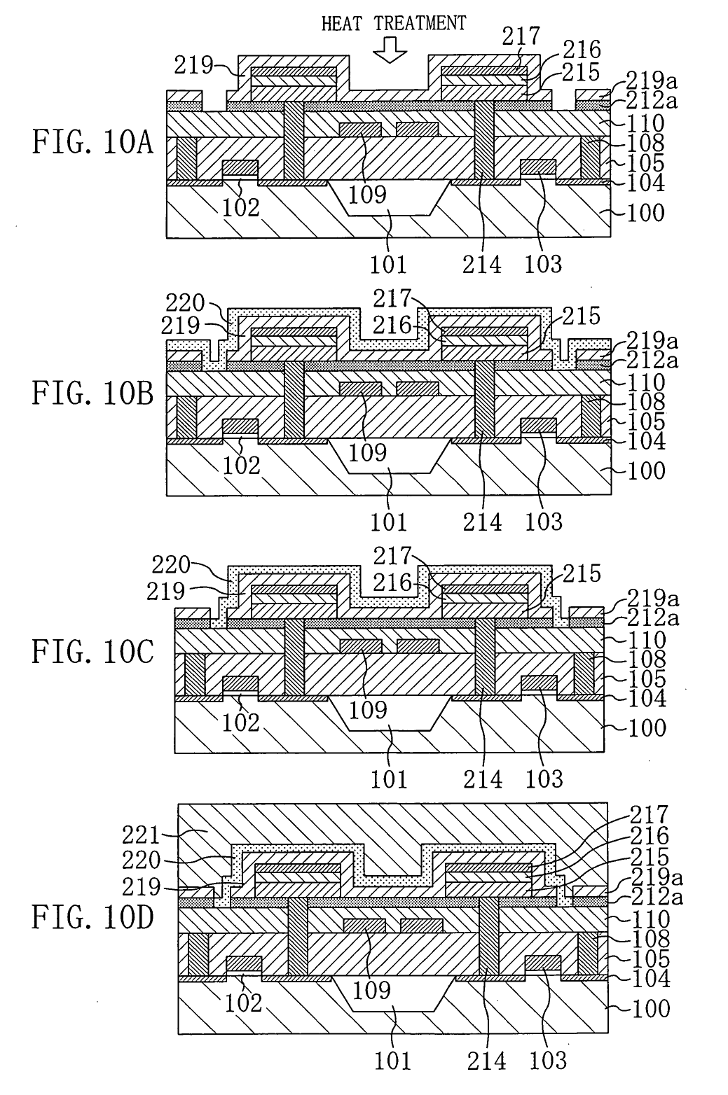

Then, as shown in FIG. 9C, an interlayer insulating film 219 is formed on the first hydrogen barrier film 212 to cover the capacitors 218. The thickness of the interlayer insulating film 219 is 20 to 200 nm, for example. By so doing, a second hydrogen barrier film 220 formed in a later step (see FIG. 10B) improves in coverage.

Then, using a mask with a desired pattern (not shown) formed on the interlayer insulating film 219, the interlayer insulating film 219 and the first hydrogen barrier film 212 are selectively etched as shown in FIG. 10A. Specifically, the mask is formed to cover the capacitors 218 and the first contact plugs 108 and certain part of the interlayer insulating film 219 and certain part of the first hydrogen barrier film 212 are selectively removed. Thus, a memory cell array including a plurality of capacitors 218 is provided on the second insulating film 110 while the first hydrogen barrier film 212a and the interlayer insulating film 219a are left on parts of the second insulating film 110 to be located above the first contact plugs 108.

According to the method for manufacturing a dielectric memory of the present embodiment, the first hydrogen barrier film 212a left on the second insulating film 110 fills the holes (the hole 400a shown in FIG. 14A) exposed on the surfaces of parts of the second insulating film 110 above the first contact plugs 108 or blocks the openings of the holes, and fills the scratches formed on the surfaces of the same parts (the scratch 401 shown in FIG. 14A).

According to the method for manufacturing a dielectric memory of the present embodiment, the first hydrogen barrier film 212 and the interlayer insulating film 219 are selectively removed without removing the second insulating film 110 as shown in FIG. 10A. Therefore, the holes (the hole 400a shown in FIG. 14A) or the scratches (the scratch 401 shown in FIG. 14A) occurred in the second insulating film 110 are prevented from being exposed outside.

Next, as shown in FIG. 10A, the capacitors 218 are sintered in a high temperature oxygen atmosphere to crystallize the dielectric film 216.

According to the method for manufacturing a dielectric memory of the present embodiment, the capacitors 218 are heat-treated while the first hydrogen barrier film 212a is left on parts of the second insulating film 110 to be located above the first contact plugs 108. By so doing, the holes (the hole 400a shown in FIG. 14A) or the scratches (the scratch 401 shown in FIG. 14A) occurred in the second insulating film 110 are not exposed outside during the heat treatment. Therefore, the entrance of oxygen into the first contact plugs 108 through the holes or scratches is prevented.

Then, as shown in FIG. 10B, a second hydrogen barrier film 220 is formed over the second insulating film 110 and the interlayer insulating film (219 and 219a) to be connected to the first hydrogen barrier film 212. By so doing, the capacitors 218 are enclosed with the first and second hydrogen barrier films 212 and 220. Therefore, when the capacitors 218 are heat-treated, hydrogen does not enter the capacitors 218, thereby preventing deterioration in characteristic of the capacitors 218.

Then, as shown in FIG. 10C, using a mask with a desired pattern (not shown) formed on the second hydrogen barrier film 220, part of the second hydrogen barrier film 220 covering the top and side surfaces of the interlayer insulating film 219a is selectively removed by dry etching.

Then, as shown in FIG. 10D, a 700 to 1500 nm thick fourth insulating film 221 made of BPSG, O₃NSG or HDP-NSG is formed over the interlayer insulating film 219a and the second hydrogen barrier film 220, and then flattened by CMP.

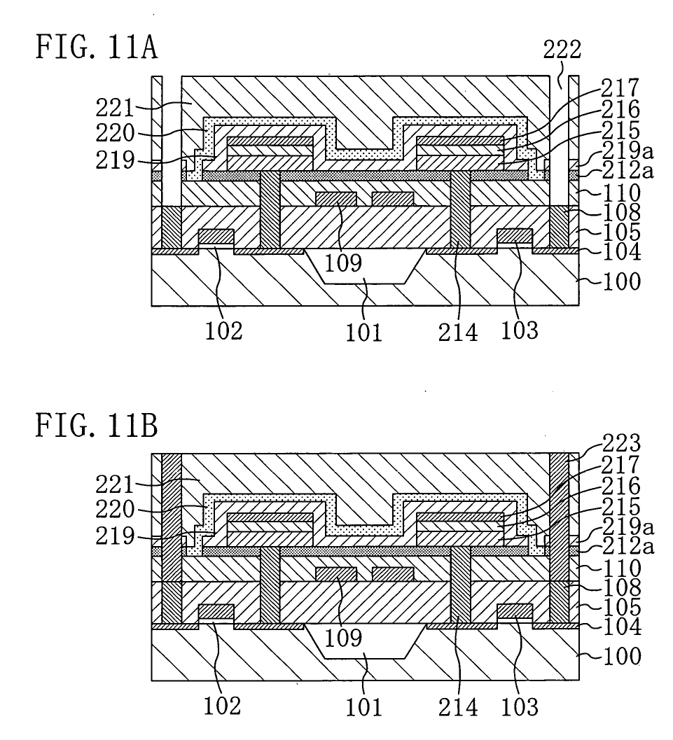

Then, on the fourth insulating film 221, a mask with a desired pattern (not shown) is formed and then the fourth insulating film 221, interlayer insulating film 219a, first hydrogen barrier film 212a and second insulating film 110 are etched using the mask. Thus, as shown in FIG. 11A, third contact holes 222 are formed in the second insulating film 110, first hydrogen barrier film 212a, interlayer insulating film 219a and the fourth insulating film 221 such that each of the third contact holes 222 reaches the top end of the first contact plug 108.

Then, a third conductive film is formed on the fourth insulating film 221 by sputtering, CVD or plating to fill the third contact holes 222. Then, CMP is performed until the surface of the fourth insulating film 221 is exposed and part of the third conductive film lying out of the third contact holes 222 is removed. Thus, as shown in FIG. 11B, third contact plugs 223 are formed to penetrate the second insulating film 110, first hydrogen barrier film 212a, interlayer insulating film 219a and fourth insulating film 221 such that each of the third contact plugs 223 is connected to the top end of the first contact plug 108 at the bottom thereof. Examples of material for the third conductive film include metals such as tungsten, molybdenum and titanium, metal nitrides such as titanium nitride and tantalum nitride, metal silicides such as titanium silicide, or polysilicon doped with Ti and Ni or Co and Cu.

In the above-described manner, a dielectric memory with COB structure including stack contacts achieved by stacks of the first contact plugs (bottom contact plugs) 108 and the third contact plugs (top contact plugs) 223 is obtained.

According to the method for manufacturing a dielectric memory of the present embodiment, the first hydrogen barrier film 212 is selectively removed such that the first hydrogen barrier film 212a is left on parts of the second insulating film 110 to be located above the first contact plugs 108 as shown in FIG. 10A.

By so doing, even if the holes (the hole 400a shown in FIG. 14A) occurred in the second insulating film 110 during the formation thereof (see FIG. 2B) are exposed on the surface of the second insulating film 110 after polishing, the first hydrogen barrier film 212a fills the holes exposed on the surfaces of parts of the second insulating film 110 above the first contact holes 108 or blocks the openings of the holes.

Further, even if the scratches (the scratch 401 shown in FIG. 14A) occurred in the surface of the second insulating film 110 through the polishing of the second insulating film 110 during the formation thereof (see FIG. 2B) reach the holes (the hole 400b shown in FIG. 14A) in the second insulating film 110, the first hydrogen barrier film 212a fills the scratches formed on the surfaces of parts of the second insulating film 110 located above the first contact plugs 108.

Therefore, when the capacitors 218 are heat-treated (see FIG. 10A), the first hydrogen barrier film 212a prevents the entrance of oxygen into the first contact plug 108 through the holes exposed on the surface of the second insulating film 110 or the scratches on the surface of the second insulating film 110. As a result, the first contact plugs 108 are prevented from oxidation and the contact resistance at the first contact plug 108 is stabilized.

Further, since the first hydrogen barrier film 212a fills the scratches (the scratch 401 shown in FIG. 14A) formed on the surfaces of parts of the second insulating film 110 located above the first contact plugs 108, the entrance of oxygen into the bit lines 109 formed on the first insulating film 105 through the scratches is prevented, thereby preventing the bit lines from oxidation.

According to the method for manufacturing a dielectric memory of the present embodiment, the first contact plugs 108 are not oxidized when the capacitors 218 are heat-treated (see FIG. 1A). Therefore, as shown in FIG. 11B, the third contact plugs 223 having stable contact resistance are formed to penetrate the second insulating film 110, first hydrogen barrier film 212a, interlayer insulating film 219a and fourth insulating film 221 to reach the first contact plugs 108, respectively.

As the first contact plugs 108 are not oxidized, the first contact plugs 108 are not etched away by a chemical solution contained in polishing slurry (e.g., hydrogen peroxide water) used to polish the third conductive film by CMP in the step of forming the third contact plugs 223 (see FIG. 11B). Therefore, the first contact plugs 108 are prevented from being removed away, thereby preventing the occurrence of cavities that spoil the stack contacts including the stacks of the first and third contact plugs 108 and 223.

Now, a brief explanation of a dielectric memory according to Embodiment 2 of the present invention will be provided.

As described above, the dielectric memory according to Embodiment 1 of the present invention includes the third insulating film 111 formed on the second insulating film 111 (see FIG. 7). In the dielectric memory according to the present embodiment, however, the first hydrogen barrier film 212a is formed on parts of the second insulating film 110 to be located above the first contact plugs 108.

That is, the first hydrogen barrier film 212a fills the holes (the hole 400a shown in FIG. 14A) exposed on the surfaces of the parts of the second insulating film 110 located above the first contact plugs 108 or blocks the openings of the holes, or fills the scratches (the scratch 401 shown in FIG. 14A) formed on the surfaces of the same parts.

Therefore, the first hydrogen barrier film 212a prevents the entrance of oxygen into the first contact plugs 108 through the holes exposed on the surfaces of the parts of the second insulating film 110 located above the first contact plugs 108 or the scratches (the scratch 401 shown in FIG. 14A) formed on the surfaces of the same parts.

The first hydrogen barrier film 212a formed on parts of the second insulating film 110 to be located above the first contact plugs 108 prevents the entrance of oxygen into the first contact plugs 108 through the holes exposed on the surfaces of the parts of the second insulating film 110 located above the first contact plugs 108 or the scratches reaching from the surfaces of the same parts to the holes. Therefore, the first contact plugs 108 are prevented from oxidation and the contact resistance at the first contact plugs 108 is stabilized.

In the dielectric memory of the present embodiment, the top faces of the first contact plugs 108 are covered with the second insulating film 110 and the first hydrogen barrier film 212a. Therefore, the first contact plugs 108 are prevented from oxidation.

According to the method for manufacturing a dielectric memory of Embodiment 1 or 2, as shown in FIG. 4B or 9B, the top electrode film 117 or 217, dielectric film 116 or 216 and bottom electrode film 115 or 215 are etched simultaneously into the capacitors 118 or 218. However, the present invention is not limited thereto.

For example, the bottom electrode film 115 or 215, dielectric film 116 or 216 and top electrode film 117 or 217 may be etched separately after the formation thereof to achieve the capacitors 118 or 218.

According to the method for manufacturing a dielectric memory of Embodiment 1 or 2, the interlayer insulating film 119 or 219 is formed on the first hydrogen barrier film 112 or 212 to cover the capacitors 118 or 218 in order to improve the coverage of the second hydrogen barrier film 120 or 220. However, the present invention is not limited thereto.

For example, referring to FIG. 5B or 10B, the second hydrogen barrier film 120 or 220 may be formed directly over the third insulating film 111 or the second insulating film 111 and the capacitors 118 or 218 to be joined to the first hydrogen barrier film 112 or 212, without forming the interlayer insulating film 119 or 219.

According to the method for manufacturing a dielectric memory of Embodiment 1 or 2, the capacitors 118 or 218 are sintered to crystallize the dielectric film 116 or 216 as shown in FIG. 5A or 10A. However, the present invention is not limited thereto. For example, the capacitors may be annealed or subjected to RTA (Rapid Thermal Anneal) to crystallize the dielectric film.

According to the method for manufacturing a dielectric memory of Embodiment 1 or 2, the fourth insulating film 221 is formed after the parts of the second hydrogen barrier film 120 or 220 located above the first contact plugs 108 are selectively removed as shown in FIG. 5C or 10C. However, the present invention is not limited thereto.

For example, if the second hydrogen barrier film 120 or 220 is made of insulating material, the selective removal of the second hydrogen barrier film 120 or 220 is not necessary. Instead, the fourth insulating film 221 may be formed directly on the parts of the second hydrogen barrier film 120 or 220 located above the first contact plugs 108.

According to the dielectric memory and the method for manufacturing the same according to Embodiment 1 or 2 of the present invention, a dielectric memory including stacked capacitors is taken as an example. However, the present invention is not limited thereto. For example, the dielectric memory and the method for manufacturing the same according to Embodiment 1 or 2 are also effective for a dielectric memory including three-dimensional capacitors.

Thus, as described above, the present invention is useful for a dielectric memory with COB structure and a method for manufacturing the same.

What is claimed is:

1. A method for manufacturing a dielectric memory comprising the steps of:
(A) forming a first insulating film on a semiconductor substrate;
(B) forming first contact plugs through the first insulating film to reach the semiconductor substrate;
(C) forming wires on the first insulating film to be electrically connected to some of the first contact plugs;
(D) forming a second insulating film on the first insulating film to cover the wires;
(E) forming a third insulating film on the second insulating film;
(F) forming a first hydrogen barrier film on the third insulating film;
(G) forming second contact plugs through the first insulating film, the second insulating film, the third insulating film and the first hydrogen barrier film to reach the semiconductor substrate;
(H) forming capacitors on the first hydrogen barrier film to be electrically connected to the second contact plugs, each of the capacitors including a bottom electrode, a dielectric film and a top electrode;
(I) selectively removing parts of the first hydrogen barrier film located above the first contact plugs which are not connected to the wires; and
(J) heat-treating the capacitors.

2. A method for manufacturing a dielectric memory according to claim 1 further comprising, after the step (J), the steps of:
(K) forming a fourth insulating film on the semiconductor substrate to cover the capacitors; and
(L) forming third contact plugs through the second insulating film, the third insulating film and the fourth insulating film to reach the first contact plugs, respectively.

3. A method for manufacturing a dielectric memory according to claim 2 further comprising the step of:
(X) forming a second hydrogen barrier film to cover the capacitors and to be joined to the first hydrogen barrier film after the step (J) and before the step (K), wherein
in the step (K), the fourth insulating film is formed on the third insulating film to cover the second hydrogen barrier film.

4. A method for manufacturing a dielectric memory according to claim 3 further comprising the step of:
forming an interlayer insulating film on the first hydrogen barrier film to cover the capacitors after the step (H) and before the step (J).

5. A method for manufacturing a dielectric memory according to claim 1, wherein the second insulating film and the third insulating film are made of the same material.

6. A method for manufacturing a dielectric memory according to claim 1, wherein the step (D) includes the step of flattening the second insulating film by CMP.

7. A method for manufacturing a dielectric memory according to claim 1, wherein the first hydrogen barrier film is made of silicon nitride.

8. A method for manufacturing a dielectric memory comprising the steps of:
(A) forming a first insulating film on a semiconductor substrate;
(B) forming first contact plugs through the first insulating film to reach the semiconductor substrate;
(C) forming wires on the first insulating film to be are electrically connected to some of the first contact plugs;
(D) forming a second insulating film on the first insulating film to cover the wires;
(E) forming a first hydrogen barrier film on the second insulating film;
(F) forming second contact plugs through the first insulating film, the second insulating film and the first hydrogen barrier film to reach the semiconductor substrate;
(G) forming capacitors on the first hydrogen barrier film to be electrically connected to the second contact plugs, each of the capacitors including a bottom electrode, a dielectric film and a top electrode;
(H) selectively removing a desired part of the first hydrogen barrier film while at least the capacitors and parts of the first hydrogen barrier film located above the first contact plugs are covered with a mask; and
(I) heat-treating the capacitors.

9. A method for manufacturing a dielectric memory according to claim 8 further comprising, after the step (I), the steps of:
(J) forming a third insulating film on the semiconductor substrate to cover the capacitors; and
(K) forming third contact plugs through the second insulating film, the first hydrogen barrier film and the third insulating film to reach the first contact plugs, respectively.

10. A method for manufacturing a dielectric memory according to claim 9 further comprising the step of:
(X) forming a second hydrogen barrier film to cover the capacitors and to be joined to the first hydrogen barrier film after the step (I) and before the step (J), wherein
in the step (J), the third insulating film is formed on the second hydrogen barrier film.

11. A method for manufacturing a dielectric memory according to claim 10 further comprising the step of:
forming an interlayer insulating film on the first hydrogen barrier film to cover the capacitors after the step (G) and before the step (I).

12. A method for manufacturing a dielectric memory according to claim 8, wherein the step (D) includes the step of flattening the second insulating film by CMP.

13. A method for manufacturing a dielectric memory according to claim 8, wherein the first hydrogen barrier film is made of silicon nitride.

14. A dielectric memory comprising:
a first insulating film which is formed on a semiconductor substrate provided with transistors;
first contact plugs which are formed through the first insulating film and connected to ones of diffusion layers in the transistors;
wires which are formed on the first insulating film;
a second insulating film which is formed on the first insulating film to cover the wires;
a first hydrogen barrier film which is formed on the second insulating film;
second contact plugs which are formed through the first insulating film, the second insulating film and the first hydrogen barrier film and connected to the other diffusion layers in the transistors;
capacitors which are formed on the first hydrogen barrier film and electrically connected to the second contact plugs, each of the capacitors including a bottom electrode, a dielectric film and a top electrode;
an interlayer insulating film which is formed on the semiconductor substrate to cover the capacitors;
a second hydrogen barrier film which is formed on the interlayer insulating film;
a fourth insulating film which is formed on the second hydrogen barrier film to cover the capacitors; and
third contact plugs which are formed through the second insulating film and the fourth insulating film to reach the first contact plugs, respectively.

15. A dielectric memory according to claim 14 further comprising:
a third insulating film which is formed between the second insulating film and the first hydrogen barrier film, wherein
the second contact plugs are formed through the first insulating film, the second insulating film, the third insulating film and the first hydrogen barrier film and
the third contact plugs are formed through the second insulating film, the third insulating film and the fourth insulating film.
